(19) United States
(12) Patent Application Publication
(10) Pub. No.: US 2009/0200682 A1
(43) Pub. Date: Aug. 13, 2009

(54) VIA IN VIA CIRCUIT BOARD STRUCTURE

(75) Inventor: Tonglong Zhang, Tustin, CA (US)

Correspondence Address: FIALA & WEAVER, P.L.L.C.;C/O CPA GLOBAL, P.O. BOX 52050, MINNEAPOLIS, MN, 55402, US

(73) Assignee: BROADCOM CORPORATION, Irvine, CA (US)

(21) Appl. No.: 12/028,166

(22) Filed: Feb. 8, 2008

(51) Int. Cl. H01L 23/535; H01L 21/44; H01L 21/4763; H05K 3/42

(52) U.S. Cl. 257/774; 174/266; 438/637; 257/E23.168; 257/E21.496

(57) ABSTRACT

Methods, systems, and apparatuses for electrical connections through circuit boards are described. A via-in-via structure in a circuit board provides two electrical signal paths. The circuit board includes a dielectric layer having opposing first and second planar surfaces. A first opening extends through the dielectric layer. An electrically conductive coating coats a surface of the dielectric layer in the first opening. An electrically insulating material substantially fills the first opening. The circuit board includes a first additional dielectric layer attached to the first planar surface, and a second additional dielectric layer attached to the second planar surface. A second opening extends through the first additional dielectric layer, the electrically insulating material filling the first opening, and the second additional dielectric layer. An electrically conductive material coats a surface of the first additional dielectric layer, the electrically insulating material, and the second additional dielectric layer in the second opening.

### BACKGROUND OF THE INVENTION

1. Field of the Invention

The present invention relates to circuit board technology, and more particularly, to electrical connections through circuit boards.

2. Background Art

Various types of circuit boards exist, including printed circuit boards (PCBs) and substrates used in integrated circuit packages. A PCB mounts electronic components, and provides electrically conductive pathways to electrically connect the mounted electronic components. A substrate in an integrated circuit package mounts one or more integrated circuit chips, and provides electrical pathways from the mounted chip(s) to electrical mounting members (e.g., pins, pads, solder balls, etc.) for the package. The electrical mounting members are used to mount the package to another circuit board.

A typical circuit board includes one or more layers of electrically conductive material laminated onto an electrically insulating substrate material. Multi-layer circuit boards are formed from alternating layers of electrically conductive material and electrically insulating material. Electrically conductive paths (e.g., traces, conductive planes, etc.) are formed in the layers of electrically conductive materials. Vias are formed in a circuit board to enable electrical connections to be formed between different electrically conductive layers of the circuit board.

A via is typically formed in a circuit board by drilling a hole in the circuit board, and plating/coating an inner surface of the hole with an electrically conductive material. The electrically conductive material plating/coating the via forms an electrical connection from a first electrically conductive layer to a second electrically conductive layer of the circuit board. A via may extend completely through a circuit board (a “through” via), may extend through a portion of the circuit board from one outer surface (a “blind” via), or may extend through a portion of the circuit board and be completely hidden from external view (a “buried” via).

An electrical signal is conducted from one electrically conductive layer to another electrically conductive layer of a circuit board by a via. Frequently, a circuit board includes electrically conductive layers that are used as ground or power signal planes. The ground and power planes have openings to allow vias to be routed through them without shorting the electrical signals being carried by the vias. However, electrical signals that use vias to pass through ground and/or power signal layers of a circuit board frequently suffer from electrical signal loss and noise. Ground and power planes may include a large amount of electrical noise due to circuit switching and other circuit functions. This noise may be undesirably coupled onto the electrical signals passing through the ground or power planes on vias. For high speed signals conducting through vias, the electrical losses/noise can be large enough to prevent proper electrical function. This problem is especially acute for single ended signals, which have less ability to reject noise than differential signals.

What are needed are ways of conducting electrical signals through circuit boards in a manner that reduces or eliminates the electrical signal loss and noise suffered by electrical signals carried on conventional vias.

### BRIEF SUMMARY

Methods, systems, and apparatuses are provided for electrical connections through circuit boards. A via-in-via structure in a circuit board provides two electrical signal paths between layers of the circuit board. The via-in-via structure includes a second via formed within a first via to provide a pair of electrical signal paths through the circuit board.

In a first implementation, using the pair of electrical signal paths, two related or unrelated electrical signals may be conducted through the circuit board by the via-in-via structure. In a second implementation, the first via may be an electrical shield for an electrical signal conducting through the second via.

In another implementation, a circuit board includes a dielectric layer having opposing first and second planar surfaces. A first opening extends through the dielectric layer. An electrically conductive coating coats a surface of the dielectric layer in the first opening. An electrically insulating material substantially fills the first opening. The circuit board includes a first additional dielectric layer attached to the first planar surface, and a second additional dielectric layer attached to the second planar surface. A second opening extends through the first additional dielectric layer, the electrically insulating material filling the first opening, and the second additional dielectric layer. An electrically conductive material coats a surface in the second opening of the first additional dielectric layer, the electrically insulating material, and the second additional dielectric layer.

In another implementation, a method of forming an electrical connection in a circuit board is provided. To form a first via, the method includes forming a first opening that extends through a dielectric layer having opposing first and second planar surfaces, and coating a surface of the dielectric layer within the first opening with an electrically conductive material. The first opening is filled with an electrically insulating material. The method further includes attaching a first additional dielectric layer to the first planar surface, and attaching a second additional dielectric layer to the second planar surface. To form a second via, the method further includes forming a second opening that extends through the first additional dielectric layer, the electrically insulating material filling the first opening, and the second additional dielectric layer, and coating a surface of the first additional dielectric layer, the electrically insulating material filling the first opening, and the second additional dielectric layer within the second opening with the electrically conductive material.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIGS. 1 and 2 show views of an example conventional via in a circuit board.

FIGS. 3 and 4 show views of an example circuit board that includes an example via-in-via structure, according to an embodiment of the present invention.

FIG. 5 shows a flowchart providing a process for forming an electrical connection in a circuit board, according to an example embodiment of the present invention.

FIGS. 6-11 show phases in the fabrication of the via-in-via structure shown in FIGS. 3 and 4, according to example embodiments of the present invention.

FIG. 12 shows the circuit board of FIG. 3 with additional dielectric material layers, according to an example embodiment of the present invention.

FIG. 13 shows a via-in-via structure, according to an example embodiment of the present invention.

FIG. 14 shows a via-in-via structure fabrication system, according to an embodiment of the present invention.

FIG. 15 shows an integrated circuit package mounted to a printed circuit board, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Conventional Vias in Circuit Boards

A typical circuit board is a composite of organic and inorganic materials with external and internal electrical connections. The circuit board allows one or more electronic components attached thereto to be mechanically supported and electrically connected among themselves.

Various types of circuit boards exist, including printed circuit boards (PCBs) and substrates used in integrated circuit packages. A PCB mounts electronic components, and provides electrically conductive pathways to electrically connect the mounted electronic components. A substrate in an integrated circuit package mounts one or more integrated circuit chips, and provides electrical pathways from the chip(s) to electrical mounting members (e.g., pins, pads, solder balls, etc.) for the package. The electrical mounting members are used to mount the package to another circuit board.

Design and manufacturing techniques for circuit boards have progressed from one or two layered structures to multi-layer boards, where ten or more layers are not uncommon. Multi-layered circuit boards are formed from alternating layers of electrically conductive materials and electrically insulating materials. For example, the electrically insulating or dielectric materials may be organic, plastic, ceramic, and tape material, among other material. Such substrates may include materials such as polyimide, “BT”, which includes a resin called bis-maleimide triazine, “FR-4,” which is a fire-retardant epoxy resin-glass cloth laminate material, “FR-5,” and/or other similar materials.

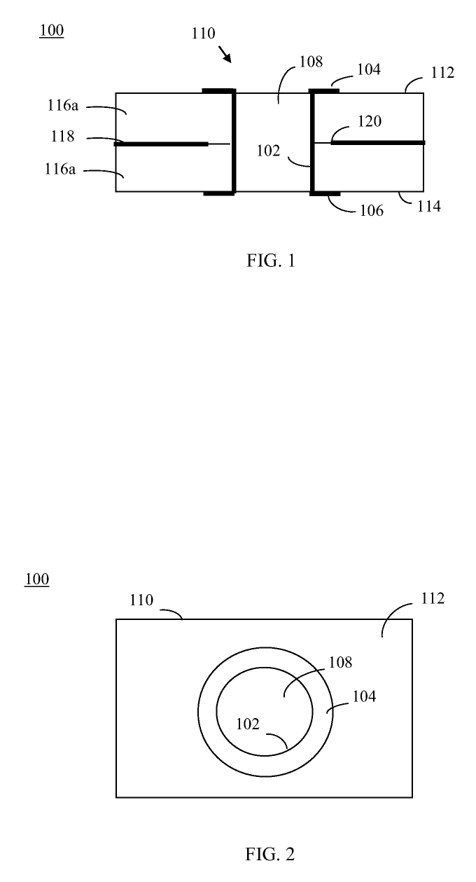

A via (also referred to as a “plated through hole”) is an electrically conductive opening through one or more dielectric layers of the circuit board, through which an electrical signal may pass. Conventionally, a via passes a single electrical signal between different conductive layers of a circuit board. For instance, FIGS. 1 and 2 show views of a circuit board 100 that includes an example conventional via 110. FIG. 1 shows a side cross-sectional view of circuit board 100, and FIG. 2 shows a top view of circuit board 100. Via 110 includes an electrically conductive coating 102, a first via pad 104, a second via pad 106, and an opening 108. As shown in FIG. 1, circuit board 100 may include a pair of layers of dielectric material—first and second dielectric material layers 116a and 116b. Alternatively, circuit board 100 may include a single layer of dielectric material, or may include additional layers of dielectric material. An electrically conductive layer 118 is located between first and second dielectric material layers 116a and 116b. Via 110 is formed through dielectric layers 116a and 116b of circuit board 100.

Opening 108 is a hole formed through dielectric material layers 116a and 116b and electrically conductive layer 118. Electrically conductive coating 102 covers a surface of first and second dielectric material layers 116a and 116b in opening 108. First via pad 104 is formed on a first surface 112 of circuit board 100 around opening 108, and second via pad 106 is formed on a second (opposing) surface 114 of circuit board 100 around opening 108. Via pads 104 and 106 are coupled to electrically conductive coating 102 of via 110. Electrically conductive coating 102 and via pads 104 and 106 are electrically conductive so that an electrical signal may be conducted through via 110 between first and second surfaces 112 and 114. For example, via pads 104 and 106 and electrically conductive coating 102 may be formed of a metal such as copper, aluminum, gold, silver, tin, nickel, lead, or a combination of metals/alloy, or may be formed of other electrically conductive material. Electrically conductive layer 118 is electrically isolated from via 110 due to an opening 120 in electrically conductive layer 118. Electrically conductive layer 118 may be a ground or power signal plane.

Via 110 may have any diameter, as desired for a particular application. For example, in one implementation, opening 108 of via 110 may have a diameter of 200 microns, and via pads 104 and 106 may have diameters of 350 microns. Alternatively, via 110 may be a micro-via, with opening 108 having a diameter that is less than 150 microns. These example dimensions for via 110 are provided for purposes of illustration, and are not intended to be limiting.

An electrical signal may be conducted by via 110 from a first electrically conductive layer of circuit board 100 that includes first via pad 104 to a second electrically conductive layer of circuit board 100 that includes second via pad 106. Via 110 conducts the electrical signal through opening 120 in electrically conductive layer 118. However, the electrical signal conducted by via 110 may suffer from electrical signal loss and may gain noise due to the proximity to electrically conductive layer 118. Electrical signal loss may occur due to parasitic capacitive coupling between via 110 and electrically conductive layer 118. When electrically conductive layer 118 is a ground or power plane, layer 118 may include a large amount of noise due to circuit switching and other circuit functions. This noise may be undesirably coupled onto the electrical signal being conducted by via 110. The electrical losses/noise can be large enough to prevent proper electrical function, particularly when the electrical signal is a high speed signal. This problem is especially acute for single ended signals, which have less ability to reject noise than differential signals.

Embodiments of the present invention provide ways of conducting electrical signals through circuit boards in a manner that reduces or eliminates electrical signal loss and noise. Example embodiments of the present invention are described in the following section.

### EXAMPLE VIA-IN-VIA-EMBODIMENTS

Example embodiments are described for providing electrical connections through circuit boards. For example, electrical connections are made through circuit boards using novel via structures. The example embodiments described herein are provided for illustrative purposes, and are not limiting. Further structural and operational embodiments, including modifications/alterations, will become apparent to persons skilled in the relevant art(s) from the teachings herein.

In embodiments, a via-in-via structure includes a second via that is formed in a first via. The first and second vias provide a pair of electrical signal paths through a circuit board. In this manner, two related or unrelated electrical signals may be passed through the circuit board by the via-in-via structure. In one example, a differential signal pair may be conducted through the circuit board using the via-in-via structure. Alternatively, an electrical signal and an associated ground signal (e.g., a transmission line) may be conducted through the circuit board using the via-in-via structure.

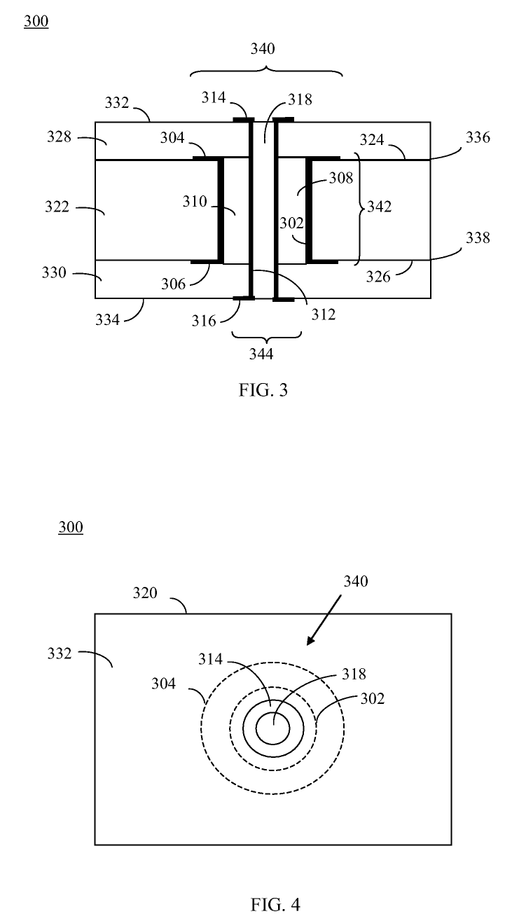

FIGS. 3 and 4 show views of an example circuit board 300 that includes a via-in-via structure 340, according to an embodiment of the present invention. FIG. 3 shows a cross-sectional view of circuit board 300, and FIG. 4 shows a top view of circuit board 300. Circuit board 300 may include features (not shown in FIGS. 3 and 4) in addition to via-in-via structure 340, as would be known to persons skilled in the relevant art(s). For example, circuit board 300 may include additional vias (via-in-via structures and/or conventional vias), traces, bond pads, ground/power rings, connectors, etc. Portions of via-in-via structure 340 that are hidden within circuit board 300 are indicated in FIG. 4 with dotted lines, for purposes of illustration. As shown in FIG. 3, via-in-via structure 340 includes a first via 342 and a second via 344. Second via 344 is formed in first via 342. Although second via 344 is shown as being co-axially aligned with first via 342 in FIGS. 3 and 4, in an alternative embodiment, an axis of second via 344 may be offset from an axis of first via 342, if desired. First and second vias 342 and 344 may be any type/size of vias, including conventional vias, micro vias, or other via type/size, as would be known to persons skilled in the relevant art(s).

As shown in FIG. 3, circuit board 300 includes a first dielectric material layer 322, a second dielectric material layer 328, and a third dielectric material layer 330. Each of dielectric material layers 322, 328, and 330 may be a single layer of dielectric material, or may include multiple layers of dielectric material that alternate with layers of electrically conductive material. As shown in FIG. 3, first dielectric material layer 322 has opposing first and second planar surfaces 324 and 326. Second dielectric material layer 328 is attached to first planar surface 324 of first dielectric material layer 322, and third dielectric material layer 330 is attached to second planar surface 326 of first dielectric material layer 322. First via 342 is formed through first dielectric layer 330, and second via 344 is formed through first-third dielectric layers 322, 328, and 330.

First via 342 includes a first opening 308 in first dielectric material layer 322, an electrically conductive coating 302, a first via pad 304, and a second via pad 306. Electrically conductive coating 302 coats a surface of first dielectric material layer 322 in first opening 308. First via pad 304 is formed on first surface 324 of first dielectric material layer 322 around opening 308, and second via pad 306 is formed on second surface 326 of first dielectric material layer 322 around opening 108. Via pads 304 and 306 are coupled to electrically conductive coating 302 of first via 342. Electrically conductive coating 302 and via pads 304 and 306 are electrically conductive so that an electrical signal may be conducted through first via 342 between first and second surfaces 324 and 326.

For example, a first electrically conductive layer 336 (e.g., containing traces and/or other electrically conductive features) may be present between first dielectric material layer 322 and second dielectric material layer 328, and a second electrically conductive layer 338 may be present between first dielectric material layer 322 and third dielectric material layer 330. A first electrical signal net having a first electrical conductor (e.g., a trace and/or electrically conductive plane) in first electrically conductive layer 336 may be coupled to first via pad 304. The first electrical signal net may have a second electrical conductor in second electrically conductive layer 338 that is coupled to second via pad 306. An electrical signal of the first electrical signal net may conduct through first via 342 from the first electrical conductor to the second electrical conductor. Alternatively, one of first and second via pads 304 and 306 may be coupled to an electrical conductor of the first electrical signal net, while the other of first and second via pads 304 and 306 is not coupled to an electrical conductor. Such an alternate configuration may be used to hold first via 342 at a particular voltage (e.g., a ground or power voltage signal), for instance.

As shown in FIG. 3, an electrically insulating material 310 substantially fills first opening 308. Electrically insulating material 310 may be any suitable electrically insulating material, such as an electrically non-conductive epoxy, polymer, or other material. In embodiments, electrically insulating material 310 may include the same material as any of first-third dielectric material layers 322, 328, and 330. First-third dielectric material layers 322, 328, and 330 may be made of any suitable electrically insulating circuit board material. For example, layers 322, 328, and 330 may be made from ceramic, plastic, tape, and/or other suitable materials. For example, layers 322, 328, and 330 may be made from an organic material such as BT (bismaleimide triazine) laminate/resin, a flexible tape material such as polyimide, a flame retardant fiberglass composite substrate board material (e.g., FR-4, FR-5, etc.), and/or further electrically insulating material.

Second via 344 includes a second opening 318, an electrically conductive material 312, a third via pad 314, and a fourth via pad 316. Second opening 318 extends through the second dielectric material layer 328, electrically insulating material 310 (filling first opening 308), and third dielectric material layer 330. Electrically conductive material 312 is located in second opening 318 on a surface of second dielectric material layer 328, electrically insulating material 310, and third dielectric material layer 330. Electrically conductive material 312 may coat the surfaces of the layers in second opening 318, as shown in FIG. 3 (similarly to electrically conductive coating 302 that coats the surface of layer 322 in first opening 308), or electrically conductive material 312 may substantially (including entirely) fill second opening 318.

Third via pad 314 is formed on a (outer) surface 332 of second dielectric material layer 328 around second opening 318, and fourth via pad 316 is formed on a (outer) surface 334 of third dielectric material layer 330 around second opening 318. Via pads 314 and 316 are coupled to electrically conductive material 312 of second via 344. Electrically conductive material 312 and via pads 314 and 316 are electrically conductive so that an electrical signal may be conducted through second via 344 between surfaces 332 and 334.

For example, a third electrically conductive layer may be present at surface 332 of second dielectric material layer 328, and a fourth electrically conductive layer may be present at surface 334 of third dielectric material layer 330. A second electrical signal net having a first electrical conductor (e.g., a trace and/or electrically conductive plane) in the third electrically conductive layer may be coupled to third via pad 314. A second electrical conductor of the second electrical signal net in the second electrically conductive layer may be coupled to second via pad 306. An electrical signal of the second electrical signal net may conduct through second via 344 from the first electrical conductor to the second electrical conductor. Alternatively, one of third and fourth via pads 314 and 316 may be coupled to an electrical conductor of the second electrical signal net, while the other of third and fourth via pads 314 and 316 is not coupled to an electrical conductor. Such an alternate configuration may be used to hold second via 344 at a particular voltage (e.g., a ground or power voltage signal), for instance.

In the embodiment of FIGS. 3 and 4, first and second vias 342 and 344 are electrically isolated from each other. In this manner, first and second vias 342 and 344 may be coupled to distinct electrical signals (e.g., first and second signals of independent signal nets). Furthermore, in an embodiment, first via 342 may perform a shielding function for second via 344. For example, first via 342 may be coupled to a ground signal corresponding to an electrical signal coupled to second via 344. Such as configuration aids in shielding the electrical signal coupled to second via 344 from other signals. In this manner, signal loss and/or noise conventionally suffered by a signal conducted by a via through a ground or power plane (e.g., electrically conductive layer 118 shown in FIG. 1) is reduced or eliminated.

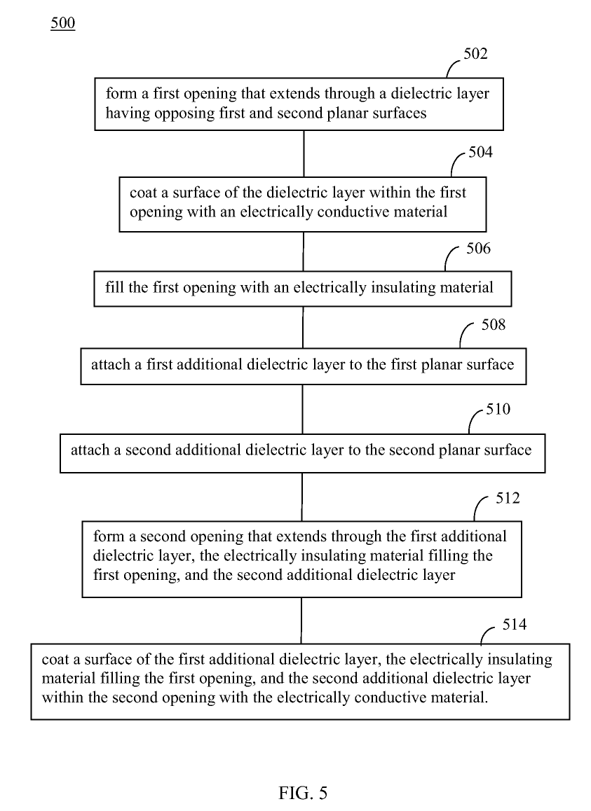

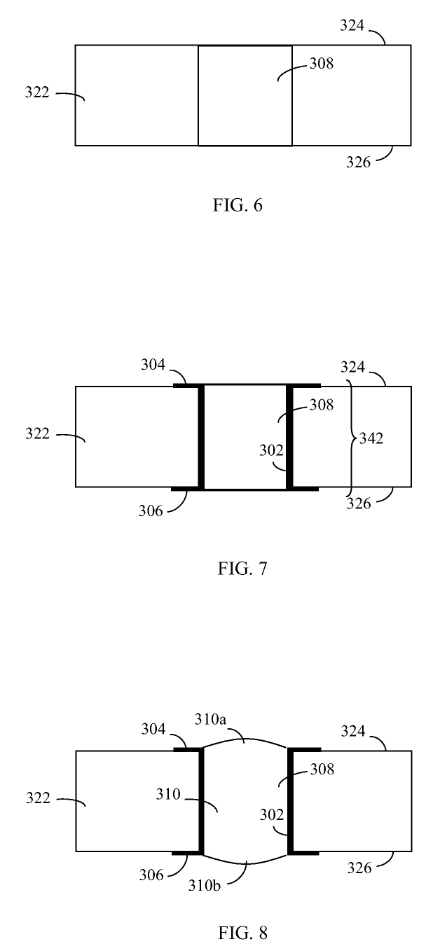

Via-in-via structure embodiments, such as via-in-via structure 340 shown in FIGS. 3 and 4, may be formed in various ways. For instance, FIG. 5 shows a flowchart 500 providing a process for forming an electrical connection in a circuit board, according to embodiments of the present invention. Via-in-via structure 340 may be formed according to flowchart 500. Flowchart 500 is described with respect to FIGS. 6-11, for illustrative purposes. FIGS. 6-11 show cross-sectional views of various phases in the formation of circuit board 300 and via-in-via structure 340 shown in FIGS. 3 and 4, according to example embodiments of the present invention. Other structural and operational embodiments will be apparent to persons skilled in the relevant art(s) based on the discussion regarding flowchart 500. Note that the steps shown in flowchart 500 do not necessarily need to be performed in the order shown. Flowchart 500 is described as follows.

Flowchart 500 begins with step 502. In step 502, a first opening is formed that extends through a dielectric layer having opposing first and second planar surfaces. For example, FIG. 6 shows a cross-sectional view of first dielectric material layer 322. As shown in FIG. 6, first opening 308 is formed through first dielectric material layer 322. First opening 308 may be formed through first dielectric material layer 322 in any manner. For example, opening 308 may be formed by a mechanical process, such as drilling, by a laser etching, by photolithographic etching, or by other hole forming process.

In step 504, a surface of the dielectric layer within the first opening is coated with an electrically conductive material. For example, as shown in FIG. 7, electrically conductive coating 302 coats the surface of first dielectric material layer 322 in opening 308. Electrically conductive coating 302 may be applied to the surface of first dielectric material layer 322 in opening 308 in any manner, conventional or otherwise, including by plating (e.g., electroplating), sputtering, vapor deposition, soldering, etc. Note that in embodiment, first and second via pads 304 and 306 may be formed during the process of coating the surface in opening 308. Alternatively, first and second via pads 304 and 306 may be formed separately from electrically conductive coating 302 (e.g., by separate plating, etc.). Electrically conductive coating 302 and first and second via pads 304 and 306 may be any electrically conductive material, including a metal such as copper, aluminum, gold, silver, tin, nickel, lead, or a combination of metals/alloy (e.g., solder), or may be formed of other electrically conductive material. Electrically conductive coating 302 and first and second via pads 304 and 306 may each be a single layer of electrically conductive material, or may be multiple layers of one or more different electrically conductive materials.

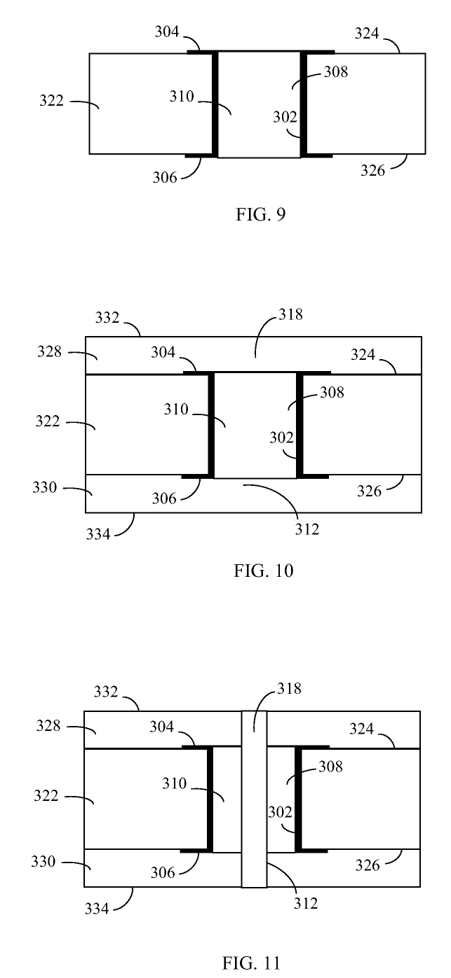

In step 506, the first opening is filled with an electrically insulating material. For example, as shown in FIG. 8, electrically insulating material 310 fills opening 308. Electrically insulating material 310 may be applied in any manner, as would be known to persons skilled in the relevant art(s), including through a targeted injection process, an applicator and squeegee process, etc. As shown in FIG. 8, due to some filling processes, excess electrically insulating material 310 may extend out of opening 308. As shown in FIG. 8, excess material 310a protrudes from opening 308 at surface 324, and excess material 310b protrudes from opening 308 at surface 326. It may be desired to remove excess electrically insulating material 310a and/or 310b so that electrically insulating material 310 is flush with surfaces 324 and 326, which are typically substantially planar surfaces. FIG. 9 shows electrically insulating material 310 having been smoothed to be flush with surfaces 324 and 326. In an embodiment, excess electrically insulating material 310a and/or 310b protruding from first opening 308 can be removed in any manner, including by milling/planing, sanding, flattening, or any other suitable processing.

In step 508, a first additional dielectric layer is attached to the first planar surface. For example, as shown in FIG. 10, second dielectric material layer 328 is attached to surface 324 of first dielectric material layer 322. Note that electrically conductive features, such via pad 304, of an electrically conductive layer (e.g., layer 336 shown in FIG. 3) may be present between layers 322 and 328.

In step 510, a second additional dielectric layer is attached to the second planar surface. For example, as shown in FIG. 10, third dielectric material layer 330 is attached to surface 326 of first dielectric material layer 322. Note that electrically conductive features, such via pad 306, of an electrically conductive layer (e.g., layer 338 shown in FIG. 3) may be present between layers 322 and 330.

Note that layers 328 and 330 may be attached to layer 322 in steps 508 and 510 according to any suitable attachment process, as would be known to persons skilled in the relevant art(s). For example, layers 328 and 330 may be attached to layer 322 by an epoxy or other adhesive material, by a lamination process, or by any other substrate layer attachment process.

In step 512, a second opening is formed that extends through the first additional dielectric layer, the electrically insulating material filling the first opening, and the second additional dielectric layer. For example, FIG. 11 shows second opening 308 formed through second dielectric material layer 328, electrically insulating material 310, and third dielectric material layer 328. Second opening 318 may be formed through second dielectric material layer 328, electrically insulating material 310, and third dielectric material layer 328 in any manner. For example, opening 318 may be formed by a mechanical process, such as drilling, by a laser etching, by photolithographic etching, or by other hole forming process.

In step 514, a surface of the first additional dielectric layer, the electrically insulating material filling the first opening, and the second additional dielectric layer within the second opening is coated with the electrically conductive material. For example, as shown in FIG. 3, electrically conductive material 312 coats the surface of second dielectric material layer 328, electrically insulating material 310, and third dielectric material layer 328 in second opening 318. Electrically conductive material 312 may be applied to the surface of second dielectric material layer 328, electrically insulating material 310, and third dielectric material layer 328 in second opening 318 in any manner, conventional or otherwise, including by plating (e.g., electroplating), sputtering, vapor deposition, soldering, etc. Note that in another embodiment, as described above, electrically conductive material 312 may substantially fill second opening 318 rather than merely covering the surfaces of second dielectric material layer 328, electrically insulating material 310, and third dielectric material layer 328 in second opening 318.

Furthermore, in embodiment, third and fourth via pads 314 and 316 may be formed during coating of the surface in opening 318. Alternatively, third and fourth via pads 314 and 316 may be formed separately from electrically conductive material 312 (e.g., by plating, etc.). Electrically conductive material 312 and third and fourth via pads 314 and 316 may be any electrically conductive material, including a metal such as copper, aluminum, gold, silver, tin, nickel, lead, or a combination of metals/alloy (e.g., solder), or may be formed of other electrically conductive material. Electrically conductive material 312 and third and fourth via pads 314 and 316 may each be a single layer of electrically conductive material, or may be multiple layers of one or more different electrically conductive materials.

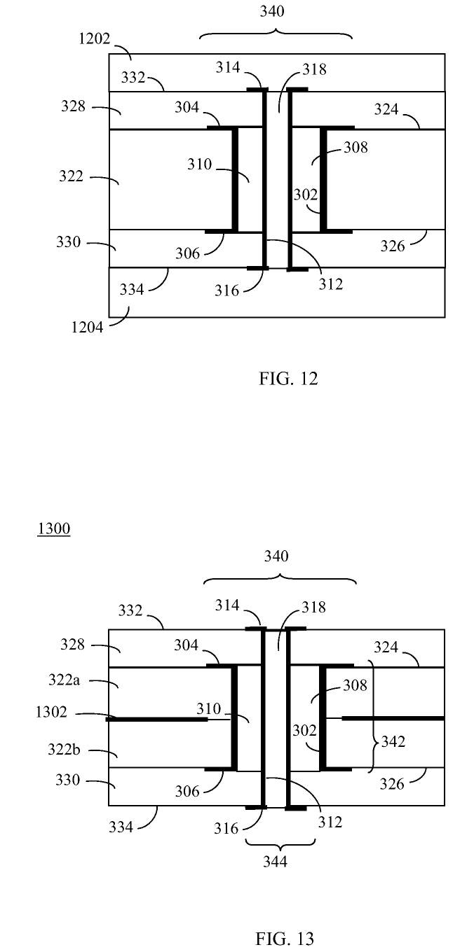

As shown in FIG. 3, via-in-via structure 340 is similar to a “through” via structure, as via pads 314 and 316 are visible on surfaces 332 and 334. In another embodiment, flowchart 500 may include an additional step, where one or more additional dielectric layers are attached to dielectric material layers 328 and 330. For example, as shown in FIG. 12, a fourth dielectric material layer 1202 is attached to surface 332 of second dielectric material layer 328, and a fifth dielectric material layer 1204 is attached to surface 334 of third dielectric material layer 330. By attaching one or more dielectric material layers to one of surfaces 332 and 334, via-in-via structure 340 may be configured similar to a “blind” via structure. By attaching one or more dielectric material layers to both of surfaces 332 and 334 (as shown in FIG. 12), via-in-via structure 340 may be configured similar to a “buried” via structure.

As described above, embodiments of the present invention reduce or eliminate signal loss and/or noise problems. For instance, FIG. 13 shows a via-in-via structure 1300, according to an embodiment of the present invention. Via-in-via structure 1300 is similar to via-in-via structure 300 shown in FIG. 3, except that first dielectric material layer 322 is shown separated into first and second dielectric material layers 322a and 322b that “sandwich” an electrically conductive layer 1302. In an embodiment, electrically conductive layer 1302 may be a ground signal layer, power signal layer, or other layer type. In conventional configurations, noise on electrically conductive layer 1302 may be coupled into an electrical signal conducting on a via (e.g., via 110) through an opening in electrically conductive layer 1302. In the embodiment of FIG. 13, an electrical signal conducting on second via 344 through an opening in electrically conductive layer 1302 is partially or entirely shielded from signal loss and/or noise by first via 342, which surrounds second via 344. First via 342 may be coupled to a ground signal associated with the electrical signal conducting on second via 344 to provide enhanced shielding.

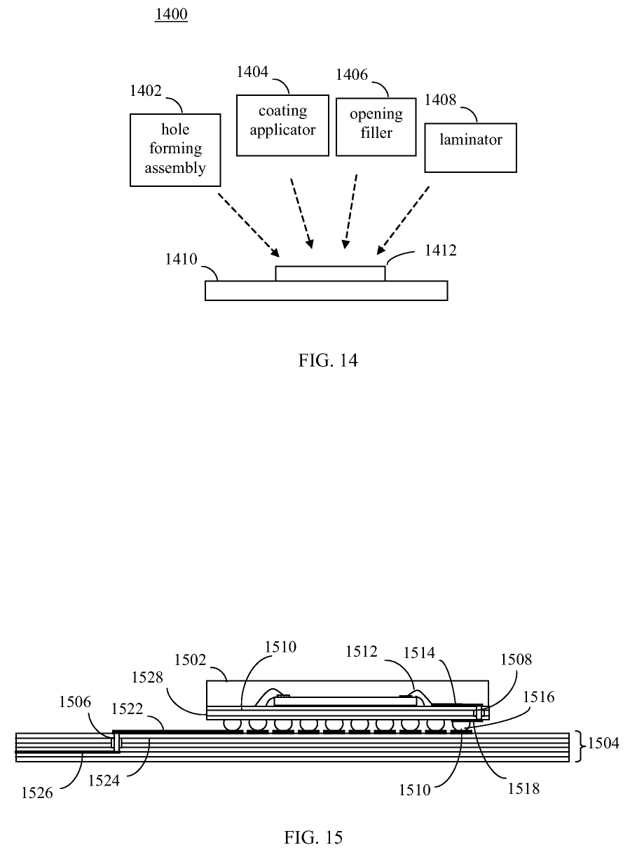

Via-in-via structures 300 and 1300 may be formed by any suitable fabrication assembly, as would be known to persons skilled in the relevant art(s) from the teachings herein. For example, FIG. 14 shows a via-in-via structure fabrication system 1400, according to an embodiment of the present invention. As shown in FIG. 14, system 1400 includes a hole forming assembly 1402, a coating applicator 1404, an opening filler 1406, and a laminator 1408. System 1400 operates on a circuit board 1412 (held on a support structure 1410) to form via-in-via structures, and optionally perform further processing of circuit board 1412.

Hole forming assembly 1402 may be used to perform steps 502 and 512 of flowchart 500 shown in FIG. 5. For example, hole forming assembly 1402 may include a drill, a laser, a photolithographic apparatus for performing etching, and/or any other hole forming device/assembly, as would be known to persons skilled in the relevant art(s).

Coating applicator 1404 may be used to perform steps 504 and 514 of flowchart 500. For example, coating applicator 1404 may include a plating assembly/device (e.g., an electroplating apparatus), a sputtering device, a vapor deposition assembly, a soldering assembly, and/or any other coating applicator device/assembly, as would be known to persons skilled in the relevant art(s).

Opening filler 1406 may be used to perform step 506 of flowchart 500. For example, opening filler 1406 may include a material injector or applicator, and/or any other opening filling device/assembly, as would be known to persons skilled in the relevant art(s). Furthermore, opening filler 1406 may include functionality to remove excess electrically insulating material (e.g., excess electrically insulating material 310a and 310b shown in FIG. 8), such as a milling apparatus, a planer, a sander, and/or any other excess material removing device/assembly, as would be known to persons skilled in the relevant art(s)

Laminator 1408 may be used to perform steps 508 and 510 of flowchart 500. For example, laminator 1408 may include a lamination apparatus, an adhesive applicator, and/or any other device/assembly for attaching layers of a circuit board, as would be known to persons skilled in the relevant art(s).

Embodiments of the present invention are applicable to any circuit board, including printed circuit boards (PCBs) and substrates of integrated circuit packages. For example, FIG. 15 shows an integrated circuit package 1502 mounted to a PCB 1504, according to an embodiment of the present invention. As shown in FIG. 15, a substrate 1528 of package 1502 has a via-in-via structure 1508. A first (outer) via of via-in-via structure 1508 is coupled to an electrical signal plane 1510 (e.g., ground plane) of substrate 1528. A first via pad of a second (inner) via of via-in-via structure 1508 is coupled to a first electrical conductor (e.g., a trace) 1514 on a top surface of substrate 1528. A second via pad of the second via of via-in-via structure 1508 is coupled to a second electrical conductor 1518 on a bottom surface of substrate 1528. Thus, in the current example, the first via of via-in-via structure 1508 may provide a shield function for a signal conducting through the second via of via-in-via structure 1508, between first and second electrical conductors 1514 and 1518.

Integrated circuit package 1502 may be any type of integrated circuit package that includes a substrate. For example, package 1502 may be a ball grid array (BGA) package, such as a plastic BGA (PBGA) package, a flex BGA package, a ceramic BGA package, a fine pitch BGA (FPBGA or FBGA) package, or other type of BGA package. Alternatively, package 1502 may be a pin grid array (PGA) package, or other integrated circuit package type that includes a substrate.

As shown in FIG. 15, PCB 1504 is a multi-layer circuit board. PCB 1504 has a via-in-via structure 1506. A first (outer) via of via-in-via structure 1506 is coupled to an electrical signal plane 1524 (e.g., ground plane) of PCB 1504. A first via pad of a second (inner) via of via-in-via structure 1506 is coupled to a first electrical conductor (e.g., a trace) 1522 on a top surface of PCB 1504. A second via pad of the second via of via-in-via structure 1506 is coupled to a second electrical conductor 1526 internal to PCB 1504. Thus, in the current example, the first via of via-in-via structure 1506 provides a shield function for a signal conducting through the second via of via-in-via structure 1506, between first and second electrical conductors 1522 and 1526.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

1. A method of forming an integrated circuit package, comprising:
forming a first opening that extends through at least one dielectric layer having opposing first and second planar surfaces;
coating a surface of the at least one dielectric layer within the first opening with an electrically conductive material;
filling the first opening with an electrically insulating material;
attaching a surface of a first at least one additional dielectric layer to the first planar surface, the surface of the first at least one additional dielectric layer having a width substantially equal to a width of the first planar surface;
attaching a second at least one additional dielectric layer to the second planar surface;
forming a second opening that extends through the first at least one additional dielectric layer, the electrically insulating material filling the first opening, and the second at least one additional dielectric layer;
coating a surface of the first at least one additional dielectric layer, the electrically insulating material filling the first opening, and the second at least one additional dielectric layer within the second opening with the electrically conductive material;
mounting an integrated circuit chip to a planar surface of the first at least one additional dielectric layer; and
attaching a plurality of electrical mounting members to a planar surface of the second at least one additional dielectric layer.

2. The method of claim 1, wherein said coating a surface of the at least one dielectric layer within the first opening with an electrically conductive material comprises:
forming a first via pad around the first opening on the first planar surface of the at least one dielectric layer; and
forming a second via pad around the first opening on the second planar surface of the at least one dielectric layer.

3. The method of claim 1, wherein said coating a surface of the first at least one additional dielectric layer, the electrically insulating material filling the first opening, and the second at least one additional dielectric layer within the second opening with the electrically conductive material comprises:
forming a third via pad around the second opening on a surface of the first at least one additional dielectric layer; and
forming a fourth via pad around the second opening on a surface of the second at least one additional dielectric layer.

4. The method of claim 3, further comprising:
coupling a first electrical signal net to the third via pad; and
coupling a second electrical signal net to at least one of the first and second via pads.

5. The method of claim 4, wherein the second electrical signal net comprises a ground plane, wherein said coupling a second electrical signal net to at least one of the first and second via pads comprises:
coupling the ground plane to at least one of the first and second via pads.

6. The method of claim 1, further comprising:
attaching a third at least one additional dielectric layer to a surface of the first at least one additional dielectric layer.

7. The method of claim 1, further comprising:
removing electrically insulating material protruding from the first opening so that the electrically insulating material is substantially planar with at least one of the first and second planar surfaces.

8. An integrated circuit package formed according to the method of claim 1.

9. An integrated circuit package, comprising:
at least one dielectric layer having opposing first and second planar surfaces;
a first opening that extends through the at least one dielectric layer;
an electrically conductive coating within the first opening on a surface of the at least one dielectric layer;
an electrically insulating material that substantially fills the first opening;
a first at least one additional dielectric layer attached to the first planar surface, a surface of the first at least one additional dielectric layer attached to the first planar surface having a width substantially equal to a width of the first planar surface;
a second at least one additional dielectric layer attached to the second planar surface;
a second opening that extends through the first at least one additional dielectric layer, the electrically insulating material filling the first opening, and the second at least one additional dielectric layer;
an electrically conductive material within the second opening on a surface of the first at least one additional dielectric layer, the electrically insulating material, and the second at least one additional dielectric layer;
an integrated circuit chip mounted to a planar surface of the first at least one additional dielectric layer; and
a plurality of electrical mounting members attached to a planar surface of the second at least one additional dielectric layer.

10. The integrated circuit package of claim 9, further comprising:
a first via pad on the first planar surface of the at least one dielectric layer around the first opening; and
a second via pad on the second planar surface of the at least one dielectric layer around the first opening.

11. The integrated circuit package of claim 10, further comprising:
a third via pad on a surface of the first at least one additional dielectric layer around the second opening; and
a fourth via pad on a surface of the second at least one additional dielectric layer around the second opening.

12. The integrated circuit package of claim 11, further comprising:
a first electrical signal net coupled to the third via pad; and
a second electrical signal net coupled to at least one of the first and second via pads.

13. The integrated circuit package of claim 12, wherein the second electrical signal net comprises a ground plane.

14. The integrated circuit package of claim 9, further comprising:
a third at least one additional dielectric layer attached to a surface of the first at least one additional dielectric layer.

15. (canceled)

16. (canceled)

17. The integrated circuit package of claim 9, wherein the at least one dielectric layer includes a first dielectric layer and a second dielectric layer, wherein the circuit board further comprises:
an electrically conductive layer between the first dielectric layer and the second dielectric layer.

18. The integrated circuit package of claim 17, wherein the electrically conductive layer is a ground layer.

19. The method of claim 1, wherein the plurality of electrical mounting members comprises a plurality of solder balls, wherein said attaching a plurality of electrical mounting members to a planar surface of the second at least one additional dielectric layer comprises:
attaching the plurality of solder balls to the planar surface of the second at least one additional dielectric layer.

20. The integrated circuit package of claim 9, wherein the plurality of electrical mounting members comprises a plurality of solder balls.
